(19) United States
(12) Patent Application Publication
(10) Pub. No.: US 2026/0130233 A1
(43) Pub. Date: May 7, 2026

(54) INTERPOSER STRUCTURE AND MANUFACTURING METHOD THEREFOR

(71) Applicant: WUHAN XINXIN SEMICONDUCTOR MANUFACTURING CO., LTD., Wuhan, Hubei (CN)

(72) Inventors: Guoliang YE, Wuhan, Hubei (CN); Sheng HU, Wuhan, Hubei (CN); Qiong ZHAN, Wuhan, Hubei (CN); Jun ZHOU, Wuhan, Hubei (CN); Peng SUN, Wuhan, Hubei (CN); Daohong YANG, Wuhan, Hubei (CN)

(21) Appl. No.: 19/117,994

(22) PCT Filed: Dec. 8, 2022
(86) PCT No.: PCT/CN2022/137498

§ 371 Date: Apr. 3, 2025

(30) Foreign Application Priority Data
Oct. 25, 2022 (CN) 202211332381.4

(51) Int. Cl. H10W 70/05; H10W 70/63

(52) U.S. Cl. CPC H10W 70/093; H10W 70/095; H10W 70/63

(57) ABSTRACT

A method for fabricating an interposer structure includes: providing a substrate; forming a first opening and filling a first conductive layer in the first opening; forming a first dielectric layer on a first surface of the substrate and forming a first redistribution metal layer in the first dielectric layer; forming a second opening and filling a second conductive layer in the second opening; forming a second dielectric layer on a second surface of the substrate and forming a second redistribution metal layer in the second dielectric layer. Through the redistribution metal layer for wiring is formed on both sides of the substrate in the thickness direction, the high-intensity interconnection requirements can be satisfied. The first opening and the second opening are formed from both sides of the substrate in the thickness direction, respectively, and communicate with each other to make up a TSV hole.

### TECHNICAL FIELD

The present invention relates to the field of integrated circuit (IC) fabrication technology and, in particular, to an interposer structure and a method for fabricating the same.

### BACKGROUND

Packaging technology came into being with the invention of integrated circuits (ICs) and is used mainly for power distribution, signal distribution, heat dissipation and protection. With the advancement of chip technology, packaging technology continues to innovate, the density of packaging and interconnections keeps increasing, the thickness of packages keeps decreasing, and three-dimensional packaging and system-in-package methods are constantly evolving. As ICs are used in more and more fields, more demanding requirements are imposed on advanced packaging by some emerging applications such as smart phones, Internet of things (IoT), automotive electronics, high-performance computing, 5G and artificial intelligence. The rapid development of packaging technology and continuous emergence of innovations have given birth to silicon interposers with through-silicon vias (TSVs) and densely arranged metal traces for addressing the problems of an insufficient wiring density associated with conventional interposers.

In conventional silicon interposer, a redistribution metal layer (RDL) is only formed on one side of the substrate. The formation method involves forming a blind hole on the front side of the substrate and filling it with conductive material to form TSV (Through-Silicon Vias), followed by forming a redistribution metal layer on the front side to tap the TSVs. The TSVs do not extend through the substrate, and it is necessary to subsequently thin the substrate from the backside until the bottom of the TSV is exposed and connect it to an IC substrate by metal bump. Use in combination with the IC substrate can provide higher strength. However, the number of redistribution metal layers tends to fail to meet the requirements of a high-density interconnection design. Further, in the silicon interposer, limited to the TSV′ depth, the thinned substrate has to have a small thickness of silicon. Consequently, the substrate tends to deform or even crack at high temperatures due to high coefficient of thermal expansion (CTE) sensitivity of silicon.

### SUMMARY OF THE INVENTION

It is an object of the present invention to provide an interposer structure and a method for fabricating the same, in which redistribution metal layer for wiring is formed on both sides of the substrate in the thickness direction, satisfying the high-intensity interconnection requirements. Moreover, the first opening and the second opening are formed from both sides of the substrate in the thickness direction, respectively, and communicate with each other to make up a TSV hole. Thus, the interposer is allowed to have a large thickness, overcoming the depth-to-width ratio limitations of galvanic metal filling and other techniques involved in TSV formation. Moreover, the interposer is made less prone to deformation even at high temperatures, and can even dispense with the use of a separate IC carrier, resulting in cost and power savings.

The present invention provides a method for fabricating an interposer structure, comprising:
providing a substrate having a first surface and a second surface that is opposite to the first surface, forming a first opening in the first surface, wherein the first opening extends from the first surface into the substrate, filling a first conductive layer in the first opening; forming a first dielectric layer on the first surface of the substrate; and forming a first redistribution metal layer in the first dielectric layer, wherein the first redistribution metal layer is electrically connected to the first conductive layer;
bonding a side of the first dielectric layer that is away from the substrate to a first carrier; forming a second opening in the second surface of the substrate, wherein the second opening extends from the second surface into the substrate so as to communicate with the first opening; and filling a second conductive layer in the second opening, wherein the second conductive layer is electrically connected to the first conductive layer;
forming a second dielectric layer on the second surface of the substrate; and forming a second redistribution metal layer in the second dielectric layer, wherein the second redistribution metal layer is electrically connected to the second conductive layer;
forming a first bonding structure on a side of the second dielectric layer that is away from the substrate, wherein the first bonding structure is electrically connected to the second redistribution metal layer; and
bonding the first bonding structure to a second carrier, removing the first carrier and then forming a second bonding structure on a side of the first dielectric layer that is away from the substrate, and removing the second carrier, wherein the second bonding structure is electrically connected to the first redistribution metal layer.

Additionally, in a cross-section taken perpendicular to the first surface, the first opening may have a minimum cross-sectional width≥10 μm and a depth≥100 μm.

Additionally, before forming the second opening in the second surface of the substrate, the substrate may be thinned from a side of the second surface, and wherein the thinned substrate has a thickness≥150 μm.

Additionally, in a cross-section taken perpendicular to the first surface, the second opening may have a minimum cross-sectional width≥5 μm and a depth≥50 μm.

Additionally, the first bonding structure and/or the second bonding structure may be a metal bump and/or a hybrid bonding structure.

Additionally, a pitch of the second bonding structure may be smaller than a pitch of the first bonding structure, wherein the second bonding structure is configured to bond a chip, and the first bonding structure is configured to bond a circuit board.

Additionally, the substrate may be a silicon substrate.

The present invention also provides an interposer structure comprising:
a substrate having a first surface and a second surface that is opposite to the first surface;
first opening, wherein the first opening extends from the first surface into the substrate and is filled with a first conductive layer;
a first dielectric layer located on the first surface of the substrate, wherein a first redistribution metal layer is formed in the first opening and is electrically connected to the first conductive layer;
a second opening, wherein the second opening extends from the second surface into the substrate and communicates with the first opening, and wherein a second conductive layer is filled in the second opening and is electrically connected to the first conductive layer;
a second dielectric layer located on the second surface of the substrate, wherein a second redistribution metal layer is formed in the second dielectric layer and is electrically connected to the second conductive layer; and
a first bonding structure and a second bonding structure, wherein the first bonding structure is located on a side of the second dielectric layer away from the substrate and is electrically connected to the second redistribution metal layer, and wherein the second bonding structure is located on a side of the first dielectric layer away from the substrate and is electrically connected to the first redistribution metal layer.

Additionally, a pitch of the second bonding structure may be smaller than a pitch of the first bonding structure, wherein the second bonding structure is configured to bond a chip, and the first bonding structure is configured to bond a printed circuit board.

Additionally, the substrate may have a thickness≥150 μm.

Compared with the prior art, the present invention may have the benefits as follows:
It provides an interposer structure and a method for fabricating the same. The method includes: providing a substrate; forming a first opening and filling a first conductive layer in the first opening; forming a first dielectric layer on a first surface of the substrate and forming a first redistribution metal layer in the first dielectric layer, the first redistribution metal layer is electrically connected to the first conductive layer; forming a second opening and filling a second conductive layer in the second opening, the second conductive layer is electrically connected to the first conductive layer; and forming a second dielectric layer on a second surface of the substrate and forming a second redistribution metal layer in the second dielectric layer, the second redistribution metal layer is electrically connected to the second conductive layer. Thus, redistribution metal layer for wiring is formed on both sides of the substrate in the thickness direction. In this way, an increased number of RDLs are formed, and the high-intensity interconnection requirements can be satisfied. The first opening and the second opening are formed by etching from both sides of the substrate in the thickness direction, respectively. The first opening and the second opening communicate with each other to make up a TSV hole. Thus, a depth of the resulting TSV hole may be doubled, and a thicker interposer may be fabricated, overcoming the depth-to-width ratio limitations of the galvanic metal filling and other techniques involved in TSV formation and increasing the thickness of the interposer. The interposer with increased thickness is less prone to deformation, thereby reducing the impact of interposer deformation under high temperature and can even dispense with the use of a separate IC carrier, resulting in cost and power savings.

### BRIEF DESCRIPTION OF THE DRAWINGS

FIG. 1 is a flowchart of a method for fabricating an interposer structure according to an embodiment of the present invention.

FIG. 2 is a schematic diagram of a structure resulting from forming a first redistribution metal layer in the method for fabricating an interposer structure according to an embodiment of the present invention.

FIG. 3 is a schematic diagram of a structure resulting from bonding a first dielectric layer to a first carrier in the method for fabricating an interposer structure according to an embodiment of the present invention.

FIG. 4 is a schematic diagram of a structure resulting from forming a second redistribution metal layer in the method for fabricating an interposer structure according to an embodiment of the present invention.

FIG. 5 is a schematic diagram of a structure resulting from forming first bonding structure in the method for fabricating an interposer structure according to an embodiment of the present invention.

FIG. 6 is a schematic diagram of a structure resulting from bonding a second dielectric layer to a second carrier in the method for fabricating an interposer structure according to an embodiment of the present invention.

FIG. 7 is a schematic diagram of a structure resulting from removing the first carrier in the method for fabricating an interposer structure according to an embodiment of the present invention.

FIG. 8 is a schematic diagram of a structure resulting from electrically connecting the resulting interposer structure to chips in the method for fabricating an interposer structure according to an embodiment of the present invention.

### LIST OF REFERENCE NUMERALS

10—substrate; f₁—first surface; f₂—second surface; 21—first conductive layer; 31—second conductive layer; 40—first dielectric layer; 50—second dielectric layer; 41—first redistribution metal layer; 51—second redistribution metal layer; 52—first bonding structure; 53—second bonding structure; 60—first carrier; 61—first bonding layer; 70—second carrier; 71—second adhesive; C1—first chip; C2—second chip.

### DETAILED DESCRIPTION

As mentioned in the Background section, existing silicon-based interposers are thin and must be combined with an IC substrate to ensure sufficient strength. Moreover, such thin interposers tend to deform at high temperatures, and since redistribution metal layers (RDL) are formed only on the front side, they still cannot meet the high-intensity interconnection requirements.

Specifically, silicon, the material from which such interposers are fabricated, has a relatively high coefficient of thermal expansion (CTE) and tends to deform due to high sensitivity at high temperature. Therefore, silicon of a smaller thickness is easier to experience cracking and other abnormalities that may occur due to deformations. The thickness of such conventional interposers is limited by existing TSV fabrication processes. The TSV structure in the interposer is formed by creating TSV holes in the silicon material using reactive ion etching technology, then an insulating layer is deposited on the sidewalls of the TSV holes, followed by filling the TSV holes with a metal layer through an electroplating process, thereby completing the fabrication of the TSV structure. Limited by the techniques involved in such processes, such as those for insulating layer deposition and for galvanic metal filling, only TSVs with a depth-to-width ratio less than 10:1 can be formed, and the formation of TSV structures with a depth-to-width ratio greater than 10:1 remains a challenge. Therefore, the thickness of conventional silicon-based interposers is greatly limited by the depth of TSVs therein.

In view of the above, embodiments of the present invention provide a method for fabricating an interposer structure. The present invention will be described in greater detail below with reference to the accompanying drawings, which illustrate specific embodiments thereof. From the following description, advantages and features of the present invention will be more apparent. Note that the figures are provided in a very simplified form not necessarily drawn to exact scale for the only purpose of helping explain the disclosed embodiments in a more convenient and clearer way.

For ease of description, in some embodiments disclosed herein, spatially relative terms, such as “above”, “below”, “top”, “under” and the like, may be used to describe one element or feature's relationship to another element or feature (or to other elements or features) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “on top of” the other elements or features. It is noted that the terms “first”, “second” and the like may be used hereunder to distinguish between similar elements without necessarily implying any particular ordinal or chronological sequence. It will be understood that the terms so used are interchangeable, whenever appropriate.

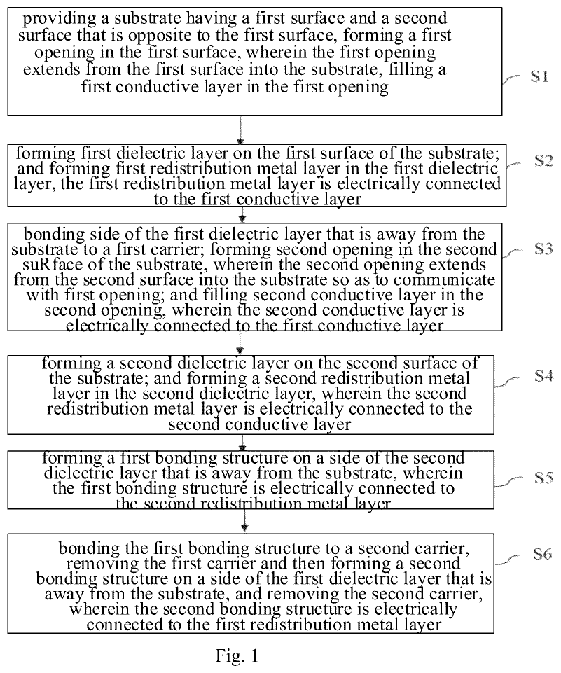

An embodiment of the present invention provides a method for fabricating an interposer structure. As shown in FIG. 1, the method includes:
in step S1, providing a substrate having a first surface and a second surface that is opposite to the first surface, forming a first opening in the first surface, wherein the first opening extends from the first surface into the substrate, filling a first conductive layer in the first opening;
in step S2, forming a first dielectric layer on the first surface of the substrate; and forming a first redistribution metal layer in the first dielectric layer, wherein the first redistribution metal layer is electrically connected to the first conductive layer;
in step S3, bonding a side of the first dielectric layer that is away from the substrate to a first carrier; forming a second opening in the second surface of the substrate, wherein the second opening extends from the second surface into the substrate so as to communicate with the first opening; and filling a second conductive layer in the second opening, wherein the second conductive layer is electrically connected to the first conductive layer;
in step S4, forming a second dielectric layer on the second surface of the substrate; and forming a second redistribution metal layer in the second dielectric layer, wherein the second redistribution metal layer is electrically connected to the second conductive layer;
in step S5, forming a first bonding structure on a side of the second dielectric layer that is away from the substrate, wherein the first bonding structure is electrically connected to the second redistribution metal layer; and
in step S6, bonding the first bonding structure to a second carrier, removing the first carrier and then forming a second bonding structure on a side of the first dielectric layer that is away from the substrate, and removing the second carrier, wherein the second bonding structure is electrically connected to the first redistribution metal layer.

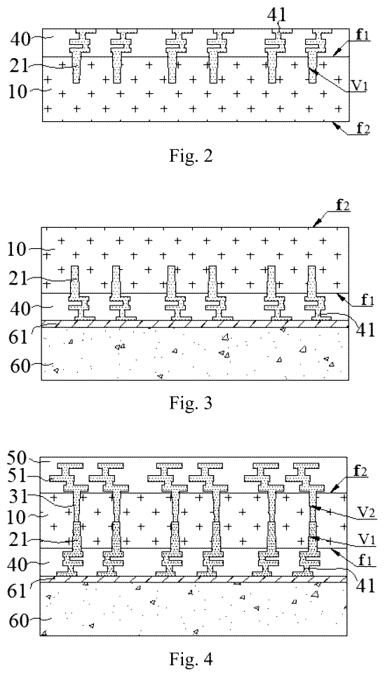

The steps in the method for fabricating an interposer structure are further described below with reference to FIGS. 2 to 8.

As shown in FIG. 2, a substrate 10 is provided, which has a first surface f₁ and a second surface f₂ that is opposite to the first surface f₁. The substrate 10 may be a silicon (Si) substrate, a germanium (Ge) substrate or a silicon germanium (SiGe) substrate. Although other materials are also possible for the substrate 10, using a silicon substrate as the substrate 10 will lead to less stress because the silicon substrate shows less CTE mismatch with silicon in a chip to be connected thereto, compared with a substrate made of another material. In other embodiments, the substrate 10 may be an organic, inorganic or other suitable material, such as silicon carbide, gallium arsenide, indium arsenide or another III-V group compound semiconductor. For example, the substrate 10 may have, but is not limited to having, a thickness of about several hundred microns, for example, a thickness in the range of 500-1200 μm.

A first opening V₁ is formed, which extends from the first surface f₁ into the substrate 10, and a first conductive layer 21 is filled in the first opening V₁. The first opening V₁ may have a depth-to-width ratio≥10:1 or <10:1. Preferably, the depth-to-width ratio of the first opening V₁ is <10:1. In a cross-section taken perpendicular to the first surface f₁, the first opening V₁ may have a minimum cross-sectional width≥10 μm and a depth≥100 μm. The first opening V₁ may be formed using an RIE technique. Alternatively, the first opening V₁ may be formed using other etching techniques, such as plasma etching, ion beam sputtering, X-ray irradiation and electron beam irradiation. A number of first openings V₁ may be formed in a direction parallel to the first surface f₁ of the substrate 10. In a cross-section taken parallel to the first surface f₁, the first opening V₁ may have a circular or quadrilateral, hexagonal or other polygonal cross-sectional shape.

The first conductive layer 21 is made of a conductive material. Examples of the conductive material may include, but are not limited to, copper (Cu), nickel (Ni), aluminum (Al), tungsten (W), titanium (Ti) and combinations thereof. The first conductive layer 21 may be a Cu layer optionally formed by electroplating. A barrier layer may be formed between sidewalls of the first opening V₁ and the first conductive layer 21. Examples of a material from which the barrier layer can be fabricated may include, but are not limited to at least one of TaN, Ta, TiN, Ti and CoW. An insulating layer of a certain thickness may be formed between the surrounding sidewall of the first opening V₁ and the first conductive layer 21 to insulate the substrate 10 from the first conductive layer 21. In examples with the barrier layer being formed, the insulating layer may be formed between the surrounding sidewalls of the first opening V₁ and the barrier layer.

A first dielectric layer 40 is formed on the first surface f₁ of the substrate 10, and a first redistribution metal layer 41 is formed in the first dielectric layer 40. The first redistribution metal layer 41 is electrically connected to the first conductive layer 21. The first dielectric layer 40 may be an organic or inorganic dielectric material. Examples of the dielectric material may include, but are not limited to, an oxide dielectric such as silicon nitride or the like. The first redistribution metal layer 41 is made of a conductive material. Examples of the conductive material may include, but are not limited to, Cu, Ni, Al, W, Ti and combinations thereof.

As shown in FIG. 3, the substrate 10 and the first dielectric layer 40 are turned upside down by 180°, as a whole, so that the second surface f₂ of the substrate 10 faces upward. A side of the first dielectric layer 40 that is away from the substrate 10 is bonded to the first carrier 60. Since fusion bonding or hybrid bonding provides higher bonding strength than temporary bonding, and because the structure will experience higher temperatures during the subsequent formation of the second opening and the second redistribution metal layer, the first dielectric layer 40 may be bonded to the first carrier 60 by fusion bonding or hybrid bonding with the aid of a first bonding layer 61. The first bonding layer 61 may be made of any material well known in the art. Examples of such a material may include, but are not limited to, oxides, nitrides and combinations thereof. Before the second opening is formed in the second surface, the substrate 10 may be thinned from the side that is away from the first dielectric layer 40 by thinning its second surface f₂. The thinned substrate 10 may have a thickness≥150 μm. Specifically, the thinning may be accomplished by performing a series of physical and chemical thinning, grinding and polishing processes on the substrate 10 until the processed surface reaches desired thickness, flatness, and roughness.

As shown in FIG. 4, a second opening V₂ is formed, which extends from the second surface f₂ into the substrate 10 and communicates with the first opening V₁. Specifically, the second opening V₂ may extend from the second surface f₂ that has undergone the thinning process into the substrate 10 and communicates with the first opening V₁. A second conductive layer 31 is filled in the second opening V₂ and is electrically connected to the first conductive layer 21. The second opening V₂ may be formed using an RIE technique. Alternatively, the second opening V₂ may be formed using other etching techniques, such as plasma etching, ion beam sputtering, X-ray irradiation and electron beam irradiation. The second opening V₂ may have a depth-to-width ratio≥10:1 or <10:1. Preferably, the depth-to-width ratio of the second opening V₂ is<10:1. In a cross-section taken perpendicular to the first surface f₁, the second opening V₂ may have a minimum cross-sectional width≥5 μm and a depth≥50 μm. A second dielectric layer 50 is formed on the second surface f₂ of the substrate 10, and a second redistribution metal layer 51 is formed in the second dielectric layer 50. The second redistribution metal layer 51 is electrically connected to the second conductive layer 31. Although the formation of the first opening V₁ has been described as preceding forming of the second opening V₂, it is also possible to form the second opening V₂ before the first opening V₁ is formed in other examples. The minimum cross-sectional width of the first opening V₁ may be smaller than, equal to or larger than the minimum cross-sectional width of the second opening V₂, as required in practical applications. The second dielectric layer 50 may be an organic or inorganic dielectric material. Examples of the dielectric material may include, but are not limited to, an oxide dielectric such as silicon nitride or the like. The second conductive layer 31 is made of a conductive material. Examples of the conductive material may include, but are not limited to, Cu, Ni, Al, W, Ti and combinations thereof. The second conductive layer 31 may be a Cu layer optionally formed by electroplating. The second redistribution metal layer 51 is made of a conductive material. Examples of the conductive material may include, but are not limited to, Cu, Ni, Al, W, Ti and combinations thereof.

Modified from an existing interposer design, the interposer structure of the present invention includes redistribution metal layers (RDL) for wiring on the respective opposite sides of the substrate 10. In this way, an increased number of RDLs are formed in the interposer, which result in a higher degree of integration and satisfy high-intensity interconnection requirements. The first opening V₁ and the second opening V₂ are formed in the opposite sides of the substrate 10 so as to communicate with each other to make up a TSV hole, in the direction perpendicular to the first surface f₁ of the substrate 10. Since the depth-to-width ratio of the TSV hole is defined as a ratio of its aggregate depth to minimum cross-sectional width, even when the depth-to-width ratios of the first opening V₁ and the second opening V₂ are both less than 10:1, the process limitations of the depth-to-width ratios below 10:1 can be overcome, thereby fabricating a TSV structure with a depth-to-width ratio greater than 10:1 and a thick interposer, overcoming the depth-to-width ratio limitations of the insulating layer deposition, galvanic metal filling and other techniques involved in TSV formation. The thicker interposer is less prone to deformation even at high temperatures, and can even dispense with the use of a separate IC carrier, resulting in cost and power savings.

With the present invention, a TSV structure with an ultra-high depth-to-width ratio can be fabricated using conventional processes, and it simultaneously reduces the process complexity of the TSV structure with high depth-to-width ratio. Moreover, it provides the advantages of a simple process, high reliability and compatibility with other semiconductor process. It effectively solves the problems associated with the etching of TSV holes in 3D structures. Devices on the opposite sides of the substrate 10 can be vertically interconnected by the second conductive layer 31 and the first conductive layer 21 in the TSV in the interposer to chips with different functions (e.g., CPU, DRAM, etc.) on the same interposer. Moreover, this vertical interconnect is shorter in length, resulting in reduced delays of signals transferred therethrough and enabling communication between the chips, which is faster and consumes less power.

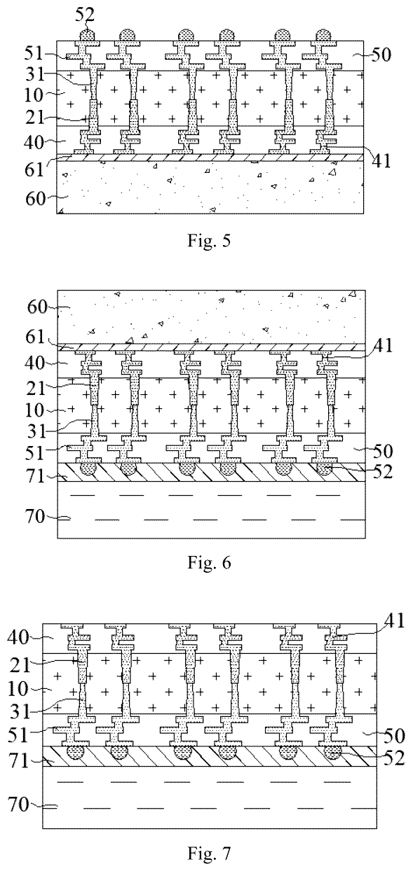

As shown in FIG. 5, first bonding structure 52 are formed on the side of the second dielectric layer 50 away from the substrate 10, and is electrically connected to the second redistribution metal layer 31. The first bonding structure 52 may be metal bump and/or hybrid bonding structure. For example, the first bonding structure 52 may be solder ball and/or solder bead. Alternatively, each of them may consist of a metal micro-pillar and a solder ball on top of the micro-pillar. Either one or more second redistribution metal layers 51 may be formed to address the need for multiple information input and output. I/O terminals may be provided on the outermost second redistribution metal layer 51, and the first bonding structure 52 may be provided at the I/O terminal.

As shown in FIG. 6, a side of the first bonding structure 52 of the interposer structure is bonded to a second carrier 70. The second dielectric layer 50 may be temporarily bonded to the second carrier 70 by a second adhesive 71. The second adhesive 71 may be a soft material, which, in case of the first bonding structure 52 being metal bump, can encapsulate the first bonding structure 52 to provide higher bonding strength. In one example, the second adhesive 71 is a temporary bonding adhesive. In another example, the second adhesive 71 is a blue film.

As shown in FIGS. 6 and 7, the first carrier 60 and/or the first bonding layer 61 is/are removed by granding.

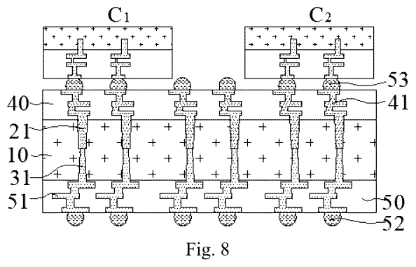

As shown in FIGS. 7 and 8, second bonding structure 53 is formed on the side of the first dielectric layer 40 away from the substrate 10, and the second bonding structure 53 is electrically connected to the first redistribution metal layer 41. The second bonding structure 53 may be metal bump and/or hybrid bonding structure. For example, the second bonding structure 53 may be solder ball and/or solder bead. Alternatively, it may consist of a metal micro-pillar and a solder ball on top of the micro-pillar. In use, a number of identical or different chips may be bonded and electrically connected to the interposer. In one example, a pitch of the second bonding structure 53 is smaller than a pitch of the first bonding structure 52. The second bonding structure 53 is configured to bond a chip and the first bonding structure 52 are configured to bond a printed circuit boards (PCB), disposing with the use of an IC substrate.

For example, a first chip Ci and a second chip C2 may be electrically connected to the interposer by second bonding structure 53, allowing the interposer to have a very large thickness. A wafer-level packaging process may be used to dice the resulting interposer structure along scribe line, and the interposer structure may be then separated into individual dies.

Embodiments of the present invention also provide an interposer structure. As shown in FIG. 8, the interposer structure includes:
a substrate 10 having a first surface and a second surface that is opposite to the first surface;
a first opening, which extends from the first surface into the substrate 10, and a first conductive layer 21 is filled in the first opening;
a first dielectric layer 40 located on the first surface of the substrate 10, a first redistribution metal layer 41 is formed in first dielectric layer 40 and is electrically connected to the first conductive layer 21;
a second opening, which extends from the second surface into the substrate 10 and communicates with the first opening, a second conductive layer 31 is filled in the second opening and is electrically connected to the first conductive layer 21;
a second dielectric layer 50 located on the second surface of the substrate 10, a second redistribution metal layer 51 is formed in the second dielectric layer 50 and is electrically connected to the second conductive layer 31; and
first bonding structure 52 and second bonding structure 53, the first bonding structure 52 located on the side of the second dielectric layer 50 away from the substrate 10 and electrically connected to the second redistribution metal layer 51, the second bonding structure 53 located on the side of the first dielectric layer 40 away from the substrate 10 and electrically connected to the first redistribution metal layer 41.

For example, a pitch of the second bonding structure 53 may be smaller than a pitch of the first bonding structure 52. The second bonding structure 53 may be configured to bond a chip, and the first bonding structure 52 may be configured to bond a PCB.

The first bonding structure 52 and/or second bonding structure 53 may be metal bump and/or hybrid bonding structure. The substrate 10 may be a silicon substrate, a germanium substrate or a silicon germanium substrate. The substrate 10 may be an organic, inorganic or other suitable material, such as silicon carbide, gallium arsenide, indium arsenide or another III-V group compound semiconductor. The substrate 10 may have a thickness≥150 μm.

To sum up, the present invention provides an interposer structure and a method for fabricating the same. The method includes: providing a substrate; forming a first opening and filling a first conductive layer in the first opening; forming a first dielectric layer on a first surface of the substrate and forming a first redistribution metal layer in the first dielectric layer, the first redistribution metal layer is electrically connected to the first conductive layer; forming a second opening and filling a second conductive layer in the second opening, the second conductive layer is electrically connected to the first conductive layer; and forming a second dielectric layer on a second surface of the substrate and forming a second redistribution metal layer in the second dielectric layer, the second redistribution metal layer is electrically connected to the second conductive layer. Thus, redistribution metal layer for wiring is formed on both sides of the substrate in the thickness direction. In this way, an increased number of RDLs are formed, and the high-intensity interconnection requirements can be satisfied. The first opening and the second opening are formed by etching from both sides of the substrate in the thickness direction, respectively. The first opening and the second opening communicate with each other to make up a TSV hole. Thus, a depth of the resulting TSV hole may be doubled, and a thicker interposer may be fabricated, overcoming the depth-to-width ratio limitations of the galvanic metal filling and other techniques involved in TSV formation and increasing the thickness of the interposer. The interposer with increased thickness is less prone to deformation, thereby reducing the impact of interposer deformation under high temperature and can even dispense with the use of a separate IC carrier, resulting in cost and power savings.

It is noted that the embodiments disclosed herein are described in a progressive manner, with the description of each embodiment focusing on its differences from others. Cross-reference can be made between the embodiments for their common or similar features. Since the method embodiments correspond to the device embodiments disclosed herein, they are described relatively briefly, and reference can be made to the device embodiments for more details.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A method for fabricating an interposer structure, comprising:
providing a substrate having a first surface and a second surface that is opposite to the first surface, forming a first opening in the first surface, wherein the first opening extends from the first surface into the substrate, filling a first conductive layer in the first opening; forming a first dielectric layer on the first surface of the substrate; and forming a first redistribution metal layer in the first dielectric layer, wherein the first redistribution metal layer is electrically connected to the first conductive layer;
bonding a side of the first dielectric layer that is away from the substrate to a first carrier; forming a second opening in the second surface of the substrate, wherein the second opening extends from the second surface into the substrate so as to communicate with the first opening; and filling a second conductive layer in the second opening, wherein the second conductive layer is electrically connected to the first conductive layer;
forming a second dielectric layer on the second surface of the substrate; and forming a second redistribution metal layer in the second dielectric layer, wherein the second redistribution metal layer is electrically connected to the second conductive layer;
forming a first bonding structure on a side of the second dielectric layer that is away from the substrate, wherein the first bonding structure is electrically connected to the second redistribution metal layer; and
bonding the first bonding structure to a second carrier, removing the first carrier and then forming a second bonding structure on a side of the first dielectric layer that is away from the substrate, and removing the second carrier, wherein the second bonding structure is electrically connected to the first redistribution metal layer.

2. The method for fabricating the interposer structure of claim 1, wherein in a cross-section taken perpendicular to the first surface, the first opening has a minimum cross-sectional width≥10 μm and a depth≥100 μm.

3. The method for fabricating an interposer structure of claim 1, wherein before forming the second opening in the second surface of the substrate, the substrate is thinned from a side of the second surface, and wherein the thinned substrate has a thickness≥150 μm.

4. The method for fabricating an interposer structure of claim 1, wherein in a cross-section taken perpendicular to the first surface, the second opening has a minimum cross-sectional width≥5 μm and a depth≥50 μm.

5. The method for fabricating an interposer structure of claim 1, wherein the first bonding structure and/or the second bonding structure is/are a metal bump.

6. The method for fabricating an interposer structure of claim 1, wherein a pitch of the second bonding structure is smaller than a pitch of the first bonding structure, wherein the second bonding structure is configured to bond a chip, and the first bonding structure is configured to bond a printed circuit board.

7. The method for fabricating an interposer structure of claim 1, wherein the substrate is a silicon substrate.

8. An interposer structure, comprising:
a substrate having a first surface and a second surface that is opposite to the first surface;
a first opening, wherein the first opening extends from the first surface into the substrate and is filled with a first conductive layer;
a first dielectric layer located on the first surface of the substrate, wherein a first redistribution metal layer is formed in the first opening and is electrically connected to the first conductive layer;
a second opening, wherein the second opening extends from the second surface into the substrate and communicates with the first opening, and wherein a second conductive layer is filled in the second opening and is electrically connected to the first conductive layer;
a second dielectric layer located on the second surface of the substrate, wherein a second redistribution metal layer is formed in the second dielectric layer and is electrically connected to the second conductive layer; and
a first bonding structure and a second bonding structure, wherein the first bonding structure is located on a side of the second dielectric layer away from the substrate and is electrically connected to the second redistribution metal layer, and wherein the second bonding structure is located on a side of the first dielectric layer away from the substrate and is electrically connected to the first redistribution metal layer.

9. The interposer structure of claim 8, wherein a pitch of the second bonding structure is smaller than a pitch of the first bonding structure, and wherein the second bonding structure is configured to bond a chip, and the first bonding structure is configured to bond a printed circuit board.

10. The interposer structure of claim 8, wherein the substrate has a thickness≥150 μm.

11. The method for fabricating an interposer structure of claim 1, wherein the first bonding structure and/or the second bonding structure is/are a hybrid bonding structure.

12. The method for fabricating an interposer structure of claim 1, wherein the first opening has a depth-to-width ratio≥10:1, and wherein the second opening has a depth-to-width ratio≥10:1.

13. The method for fabricating an interposer structure of claim 1, wherein the first opening has a depth-to-width ratio≥10:1, and wherein the second opening has a depth-to-width ratio<10:1.

14. The method for fabricating an interposer structure of claim 1, wherein the first opening has a depth-to-width ratio<10:1, and wherein the second opening has a depth-to-width

15. The method for fabricating an interposer structure of claim 1, wherein the first opening has a depth-to-width ratio<10:1, and wherein the second opening has a depth-to-width ratio<10:1.

16. The interposer structure of claim 8, wherein the first opening has a depth-to-width ratio≥10:1, and wherein the second opening has a depth-to-width ratio≥10:1.

17. The interposer structure of claim 8, wherein the first opening has a depth-to-width ratio≥10:1, and wherein the second opening has a depth-to-width ratio<10:1.

18. The interposer structure of claim 8, wherein the first opening has a depth-to-width ratio<10:1, and wherein the second opening has a depth-to-width ratio≥10:1.

19. The interposer structure of claim 8, wherein the first opening has a depth-to-width ratio<10:1, and wherein the second opening has a depth-to-width ratio<10:1.
